(19) United States
(12) Patent Application Publication
(10) Pub. No.: US 2005/0211970 A1
(43) Pub. Date: Sep. 29, 2005

(54) Metal nano-objects, formed on semiconductor surfaces, and method for making said nano-objects

(76) Inventors: Marie D'Angelo, PARIS (FR); Victor Aristov, Moscow (RU); Patrick Soukiassian, Les Cheureuse (FR)

Correspondence Address: Thelen Reid & Priest, PO Box 640640, San Jose, CA, 95164-0640, US

(21) Appl. No.: 10/520,647

(22) PCT Filed: Jul. 4, 2003
(86) PCT No.: PCT/FR03/02093

§ 371 Date: Jan. 5, 2005

(51) Int. Cl. H01L 29/06; H01L 31/072; H01L 31/0328

(52) U.S. Cl. 257/14; 257/4; 257/77; 257/621; 257/9; 977/DIG. 1

(57) ABSTRACT

Metallic nano-objects, formed on surfaces of semiconductors, and a process for manufacturing these nano-objects.

The invention is applicable in nano-electronics and for example provides a means of obtaining nano-objects (4) by depositing a metal on a prepared surface (2) of cubic SiC.

### TECHNICAL DOMAIN

This invention relates to metallic nano-objects formed on the surfaces of a semiconductor and more particularly a semiconductor with a large gap, in other words with a large forbidden band width, and a process for manufacturing these nano-objects.

More particularly, the invention relates to metallic nano-objects, for example such as atomic threads, single dimensional nano-structures and metallic quantum dots, particularly formed on silicon carbide surfaces, and a process for manufacturing such nano-objects.

The invention is particularly applicable to the nano-electronics field.

### STATE OF PRIOR ART

Nano-objects are manufactured by auto-organisation, particularly at or above room temperature, without individual manipulation of atoms, particularly by near field microscopy, which is usually done cold (using liquid nitrogen or liquid helium) to prevent migration of atoms (see documents [7] to [9] mentioned below).

Further information about surface treatment (particularly semiconducting surfaces) and the manufacture of nanostructures, and particularly single-dimensional nanostructures, can be obtained in the following documents:

[1]. Electronic promotion of silicon nitridation by alkali metals.

P. Soukiassian, H. M. Bakshi, H. I. Stamberg, Z. Hurych, T. Gentle and K. P. Schuette Physical Review Letters 59, 1488 (1987)

[2]. CH₃CI adsorption on a Si(100)2×1 surface modified by an alkali metal over layer studied by photoemission using synchrotron radiation

T. M. Gentle, P. Soukiassian, K. P. Schuette, M. H. Bakshi and Z. Hurych

Surface Science Letters 202, L 568 (1988)

[3]. Nitridation of silicon and other semiconductors using alkali metal catalysts

P. Soukiassian

U.S. Pat. No. 4,735,921 A
[4]. Process of depositing an alkali metal layer onto the surface of an oxide superconductor

P. Soukiassian and R. V. Kasowski

U.S. Pat. No. 4,900,710 A

[5]. Fils atomiques de grande longueur et de grande stabilité, procédé de fabrication de ces fils, application en nanoélectronique

G. Dujardin, A. Mayne, F. Semond and P. Soukiassian

French patent application No. 96 15435, Dec. 16, 1996 (see also U.S. Pat. No. 6,274,234 A)

[6]. Couche monoatomique de grande taille, en carbone de type diamant, et procédé defabrication de cette couche

V. Derycke, G. Dujardin, A. Mayne and P. Soukiassian

French patent application No. 98 15218, Dec. 2, 1998

[7]. L. J. Whitman, J. A. Stroscio, R. A. Dragoset and R. J. Celotta, Science 251, 1206 (1991)

[8]. T. C. Shen, C. Wang, G. C. Abaln, J. R. Tacker, J. W. Lyding, Ph. Avouris and R. E. Walkup, Science 268, 1590 (1995)

[9]. M. F. Crommie, C. P. Lutz, D. M. Eigler and E. J. Heller, Surf. Rev. Lett. 2, 127 (1995)

### PRESENTATION OF THE INVENTION

This invention proposes metallic nano-objects such as atomic threads, single-dimensional nanostructures and metallic quantum dots, that can be very useful in the nano-electronics and opto-electronics fields.

The invention also solves the problem of manufacturing such nano-objects on the surface of a large gap semiconductor, particularly silicon carbide.

This is an auto-organised fabrication on this surface.

Candidate substrates for such organisation are substrates for which the surface diffusion barrier is anisotropic as a function of a parameter such as the temperature, a mechanical stress, etc.

Nano-objects are made by controlling the very delicate balance between adsorbate-adsorbate and adsorbate-substrate interactions (the adsorbate being the metal) and controlling the metal atom diffusion barrier.

In one particularly advantageous embodiment, the invention is used to obtain atomic threads and nano-structures of a metal, particularly silver, along a direction perpendicular to the direction of the atomic lines or atomic threads made of silicon that were previously formed on the surface of a silicon carbide substrate.

Specifically, this invention relates firstly to a set of nano-objects, particularly atomic threads, single dimensional nano-structures and quantum dots, this set being characterised in that the nano-objects are made of a metal and are formed on the surface of a substrate made of a monocrystalline semiconducting material.

This monocrystalline semiconducting material may be chosen from among monocrystalline silicon carbide, monocrystalline diamond, covalent monocrystalline semiconductors, and composite monocrystalline semiconductors.

This substrate may be a monocrystalline substrate of silicon carbide in the cubic phase.

According to one particular embodiment of the set according to the invention, the surface is a cubic silicon carbide surface, rich in β-SiC (100) 3×2 silicon.

Then nano-objects may be three-dimensional clusters of the metal on the surface.

According to one advantageous embodiment of the invention, the clusters are distributed in an orderly manner on the surface and thus form a lattice of metal dots.

According to another particular embodiment, the surface is a cubic silicon carbide surface which is Si terminated, β-SiC(100) c(4×2) and the nano-objects are parallel atomic threads or parallel single-dimensional nanometric strips of the metal.

The surface may comprise parallel atomic threads of Si, the atomic threads and single-dimensional strips of the metal being perpendicular to these atomic threads of Si.

The surface may comprise passivated areas and non-passivated areas, the nano-objects being formed on these non-passivated areas of the surface.

This invention also relates to a process of making a set of nano-objects in which a surface of a substrate made of a monocrystalline semiconducting material is prepared, and a metal is deposited on the surface thus prepared.

This monocrystalline semiconducting material may be chosen from among monocrystalline silicon carbide, monocrystalline diamond, covalent monocrystalline semiconductors and monocrystalline composite semiconductors.

This substrate may be a monocrystalline substrate of silicon carbide in the cubic phase.

The metal may be deposited at a temperature greater than room temperature.

According to a first particular embodiment of the process according to the invention, a surface of cubic silicon carbide rich in silicon β-SiC(100) 3×2 is prepared, and the metal is deposited on the surface thus prepared.

According to a second particular embodiment, a silicon carbide surface which is Si terminated β-SiC(100) c(4×2) is prepared. The metal is deposited at room temperature on the surface thus prepared and, by surface migration of metal atoms along lines of Si—Si dimers of the surface c(4×2), one obtains atomic threads of the metal that are parallel to the lines of Si—Si dimers or silicon threads.

A thermal annealing of the substrate can then be carried out at a temperature below the total desorption temperature of the metal.

The result obtained is atomic threads parallel to each other or single-dimensional nanometric strips parallel to each other, of the metal on the surface. Thus, these atomic threads and these single-dimensional strips of the metal, thus prepared at a higher temperature, are perpendicular to the atomic threads of Si.

The metal may be deposited by evaporation in vacuum or in an inert atmosphere.

Passivated areas can be formed on the prepared surface and the metal can then be deposited on non-passivated areas of this surface.

In this invention, the metal may be chosen from among metals for which the d band is full, jellium type metals, alkaline metals (particularly sodium and potassium) and transition metals.

Instead of using a thermal annealing, a laser can be used to obtain desorption of metal either by thermal interaction of the beam emitted by this laser over the surface covered with metal, or by desorption of the metal induced by electronic transitions (DIET).

In the process according to the invention, the surface may be an sp type C terminated surface, namely the β-SiC(100) c(2×2) surface.

This surface may comprise atomic lines of sp3 type C.

According to the invention, we can then form atomic threads of the metal that are either parallel or perpendicular to the atomic lines of C.

According to one particular embodiment of the invention, a lattice of metal dots is formed on the surface of the substrate made of monocrystalline semiconducting material, the substrate material located under the dots is locally transformed and the lattice of dots is eliminated to thus obtain a super-lattice of dots made of the transformed material.

Preferably, the local transformation of the substrate material is chosen from among oxidation, nitridation and oxynitridation to obtain a super-lattice of dots made of the oxide, nitride or oxynitride of the material.

### BRIEF DESCRIPTION OF THE DRAWINGS

This invention will be better understood after reading the description of example embodiments given below purely for guidance, and in no way limitative, with reference to the appended figures, wherein:

FIG. 1 is a diagrammatic view of three-dimensional metallic clusters obtained according to the invention,

FIG. 2 is a diagrammatic top view of metallic atomic threads obtained on accordance with the invention and parallel to the atomic lines of Si,

FIG. 3 is a diagrammatic top view of metallic atomic threads and single-dimensional strips obtained according to the invention and perpendicular to the atomic lines of Si,

FIG. 4 is a diagrammatic top view of such atomic threads and single-dimensional strips obtained according to the invention, on non-passivated areas of a silicon carbide surface,

FIG. 5 shows a diagrammatic view of a lattice of sodium clusters obtained in accordance with the invention on an SiC substrate,

FIG. 6 shows a diagrammatic sectional view of this substrate, carrying a super-lattice of silica dots obtained by a process according to the invention, and

FIG. 7 shows LEED photographs of a clean surface β-SiC(100) 3×2 (A), of the same surface covered by Na clusters and organised into a 3×1 lattice (B) and of the same surface covered by Na clusters and organised into a 3×2 lattice (C).

### DETAILED PRESENTATION OF PARTICULAR EMBODIMENTS

We will now give a first example of the process according to the invention, used to manufacture silver clusters.

We start by preparing a cubic silicon carbide surface, rich in silicon β-SiC(100) 3×2, in other words a plane surface of silicon carbide SiC in the β-SiC(100) cubic phase, rich in silicon and with a 3×2 surface reconstruction.

This type of preparation is described in various documents mentioned above, particularly document [5] to which we will refer.

A small quantity of silver is deposited by vacuum evaporation onto this surface rich in Si and with a 3×2 structure, for example starting from a silver source arranged facing the surface and heated by a tungsten filament.

By forming an image of the surface by STM or Scanning Tunnelling Microscopy, it is observed that silver does not wet the surface and forms three-dimensional clusters with a size varying from 0.9 nm to 3 nm, and therefore capable of forming quantum dots.

The number, size and spacing of these clusters or islands can vary as a function of the quantity of silver deposited and annealing temperatures. This growth mode indicates dominant interaction between silver atoms.

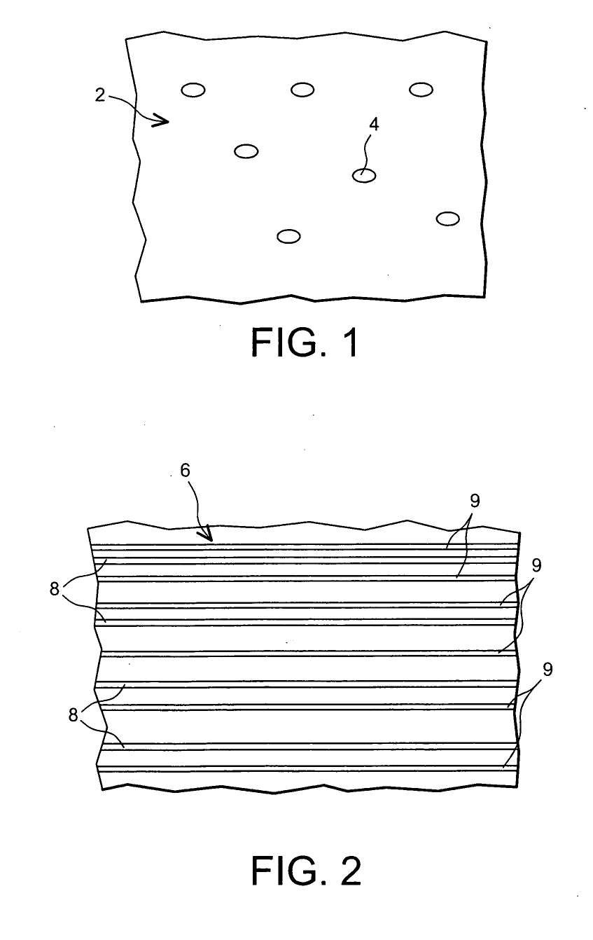

FIG. 1 shows a diagrammatic top view of the surface 2 on which the clusters 4 are formed.

For information purposes only and in no way limitatively, the silver deposit takes place in a chamber in which the pressure is less than 2×10⁻⁸ Pa and for example is equal to 6×10⁻⁹ Pa; the distance between the surface and the silver source is equal to about 15 cm; the current passing through the silver source throughout deposition is equal to 4 A; the deposition time is between 2 minutes and 8 minutes (8 minutes corresponding approximately to a single layer of silver); the deposition takes place leaving the SiC sample at room temperature (about 20° C.). The necessary annealing operations are done at about 500° C. The annealing temperature can be varied to adjust the migration velocity of metal atoms (the migration velocity increases with the temperature) and the quantity of desorbed metal (that increases with the temperature), and therefore to vary the size and spacing of the clusters.

Note that silver evaporates completely during a short annealing at about 700° C. for a few tens of seconds.

We will now give a second example of the process according to the invention which makes it possible to manufacture single dimensional strips of silver or silver threads.

We will start by preparing a cubic silicon carbide surface which is Si terminated β-SiC(100) c(4×2), in other words a surface of SiC in β-SiC(100) cubic phase, this surface being Si terminated and c(4×2) reconstructed.

Furthermore, parallel auto-organised atomic lines of silicon rest on this surface, these lines forming lines of Si—Si dimers.

Refer to document [5] which explains how straight lines of Si—Si dimers (atomic lines) are obtained on the surface of a monocrystalline substrate of SiC in the β-SiC(100) cubic phase that is transformed so that its surface is 3×2 terminated and that is then suitably annealed.

Thus, this 3×2 symmetry surface is transformed by thermal annealings at 1100° C. until it has an atomic scale organisation (reconstruction) with c(4×2) symmetry.

Silver is deposited on the β-SiC(100) c(4×2) Si surface thus obtained, under the same conditions as in the first example.

It is found that at room temperature, the silver atoms diffuse on the surface slowly, along the lines of dimers, giving metal atomic threads parallel to these lines.

FIG. 2 shows a diagrammatic top view of the surface 6 supporting the parallel lines 8 of Si—Si dimers and the atomic threads of metal 9 that are parallel to these lines.

When the surface is covered with silver, annealing is done below the total desorption temperature of silver (700° C.).

The silver layer is selectively desorbed and atoms remaining on the surface are organised to make single dimensional nanometric parallel strips of silver, or parallel atomic threads of silver. The direction of these atomic threads and these single-dimensional strips is perpendicular to the lines of dimers.

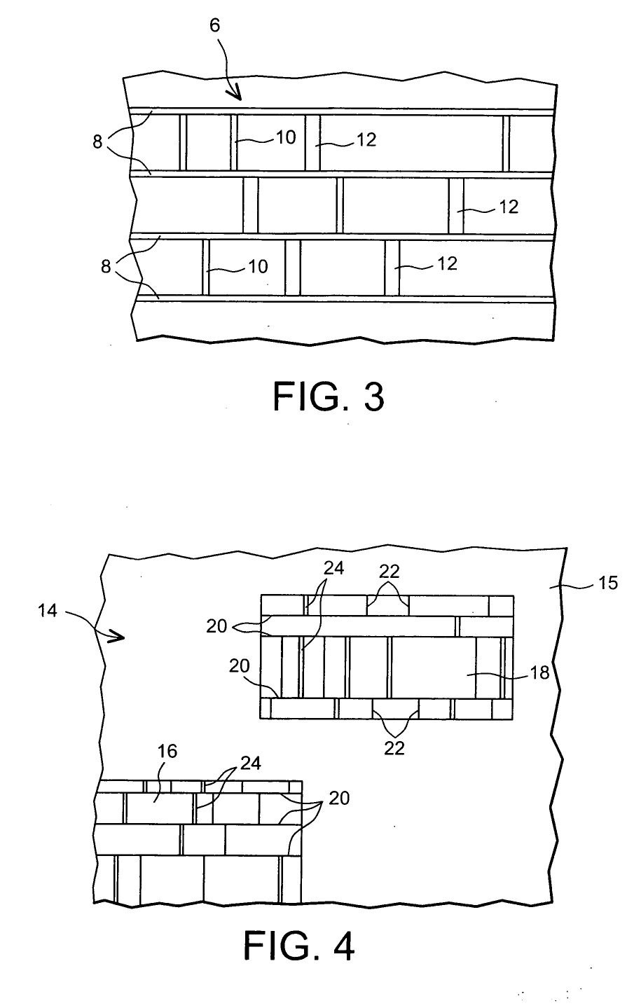

FIG. 3 shows a diagrammatic top view of the surface 6 supporting the parallel lines 8 of Si—Si dimers and the atomic threads of silver 10 together with the single-dimensional nanometric strips of silver 12.

For guidance purposes only and in no way limitatively, in the second example the silver deposition takes place in a chamber at a pressure equal to 2.1×10⁻⁹ Pa; silver is deposited for 8 minutes using a silver source through which a 4 A current passes; the sample is left at room temperature during the silver deposition; after the deposition, the sample is annealed by passing a current of 0.5 A through it for 5 minutes.

Consequently, silver threads can be constructed perpendicular to the atomic threads of Si (see document [5]).

This is extremely important for building up artificial lattices at a sub-nanometric scale, that can be very useful in nano-electronics.

We can replace silver by other metals with a full d band, such as gold or copper, or by jellium type metals such as aluminium.

Remember that a jellium type metal is a metal for which electron gas is fairly homogenous and for which positive ionic charges are largely smeared within the entire volume of the metal to give a positive and uniform background.

Silver can also be replaced by transition metals, for example such as Mo, W, Ta, Nb, Co, Fe, Mn, Cr, Ti.

With metals with magnetic characteristics, the invention can be used to dope or manufacture nanostructures, for example with magnetic properties that are attractive in spin electronics.

Silver can also be replaced by other metals such as alkaline metals that are remarkable catalysts for surface reactions with organic or inorganic molecules (see documents [1] and [2]).

Therefore, reactions on the atomic scale can be provoked and a very localised passivation, for example by oxidation, nitridation or oxynitridation, or a manufacturing of silicones at atomic or molecular scales can be encouraged.

Alkaline metals also have the remarkable property of considerably reducing the electron work function, and reaching the negative electro-affinity condition, in other words forming natural electron emitters. This invention enables this emission to take place starting from nanostructures of alkaline metals (for example Cs, Rb, K or Na).

Instead of using vacuum evaporation to deposit metal, this evaporation can be done at a higher pressure, in an inert atmosphere (rare gas, etc.).

Concerning the second example, note that the process according to the invention can be used to selectively control migration or desorption of atoms of the metal (for example silver) by varying the temperature. A variation of the temperature acts on the movement of Si—Si dimers on SiC or provokes this movement.

In a variant of this second example, the surface of cubic SiC, Si terminated β-SiC(100) c(4×2) is prepared without atomic lines of silicon, metal is deposited and annealing is carried out at a temperature below the total metal desorption temperature.

As before, one thus obtains atomic threads of the metal and/or single-dimensional nanometric strips of this metal. These atomic threads and these single dimensional strips are parallel to each other and are perpendicular to the direction along which parallel lines of Si—Si dimers would be formed.

In another example of the invention, a prepared surface of a cubic SiC sample is locally passivated using hydrogen and the atomic threads and/or single dimensional strips of the metal are formed in the non-passivated areas.

FIG. 4 is a diagrammatic top view of the locally passivated surface 14 thus comprising passivated areas such as area 15 and non-passivated areas 16 and 18. The parallel atomic lines of silicon that are present in these areas 16 and 18 are marked with reference 20. Atomic threads 22 of metal and single-dimensional strips 24 of this metal can also be seen, formed in these areas perpendicular to the lines 20.

In order to locally passivate the surface, areas that are not to be passivated are covered by a photoresist layer, and this photoresist layer is eliminated after passivation of uncovered areas.

If the direction of lines of Si—Si dimers is known in advance, non-passivated rectangular areas can be formed with one of their sides parallel to this direction.

To passivate the cubic SiC surface using hydrogen, this surface is prepared so as to have a controlled organisation with c(4×2) symmetry at atomic scale. This surface is then exposed to molecular hydrogen until saturation. The SiC is kept at room temperature during exposure to molecular hydrogen.

For example, cubic SiC is placed in a treatment chamber in which the pressure is kept at less than 5×10⁻¹⁰ hPa, and is heated by passing an electrical current directly in this SiC substrate. The substrate is heated to 650° C. for several hours and then increased to 1100° C. for one minute several times.

By means of a silicon source heated to 1300° C. several single layers of silicon are deposited on the (100) surface of the cubic SiC.

By means of thermal annealing at 1000° C. some of the deposited silicon is evaporated in a controlled manner until the surface has an organisation at the atomic scale (reconstruction) with 3×2 symmetry. This surface symmetry may be controlled by electron diffraction.

Thermal annealings at 1100° C. are applied to transform the surface with 3×2 symmetry until it has an organisation at the atomic scale (reconstruction) with c(4×2) symmetry.

This surface is then exposed to ultra pure molecular hydrogen at low pressure (10⁻⁸ hPa).

The surface is kept at room temperature during this exposure.

The SiC surface is exposed until saturation (more than 50 L).

This saturation may be controlled by a scanning tunnelling microscope or by a valence band photoemission technique.

Instead of using an Si terminated surface, all the processes described above may also be used on an sp type C terminated surface, the β-SiC(O)c(2×2) surface that may itself include sp3 type atomic lines of C (see document [6]).

According to the invention, we can thus form atomic threads of metal that are either parallel or perpendicular to the atomic lines of carbon.

In the following, we will consider other examples of this invention, namely:
obtaining sodium clusters on the surface of a semiconducting substrate, particularly a monocrystalline substrate of silicon carbide in the cubic phase,
more particularly, obtaining this type of cluster distributed in an orderly manner on the surface of this substrate and thus forming a super-lattice of sodium dots, of the type of the set of clusters in FIG. 1 in which the distribution of clusters is substantially regular; and
obtaining a super-lattice of silica dots on the substrate (remember that we have already given examples of the invention in the above, for local passivation using alkaline metals).

The sodium deposit on β-SiC(100) 3×2, which is the Si rich surface of cubic silicon carbide, has been studied. Unlike the case of the Si terminated β-SiC(100) c(4×2) surface on which Na and other alkaline metals are adsorbed in the form of a metallic film with a thickness approximately equal to the size of an atom, in this case Na is adsorbed in the form of spherical shaped metallic clusters, which is unprecedented for an alkaline metal on the surface of a semiconductor: this does not occur on the corresponding surfaces of silicon or conventional III-V composite semiconductors (therefore not including III-V nitrides). This means that the adsorbate-adsorbate interaction on this Si rich surface is more important than the adsorbate-substrate interaction. This behaviour should be compared with the behaviour of silver on the same surface (see above).

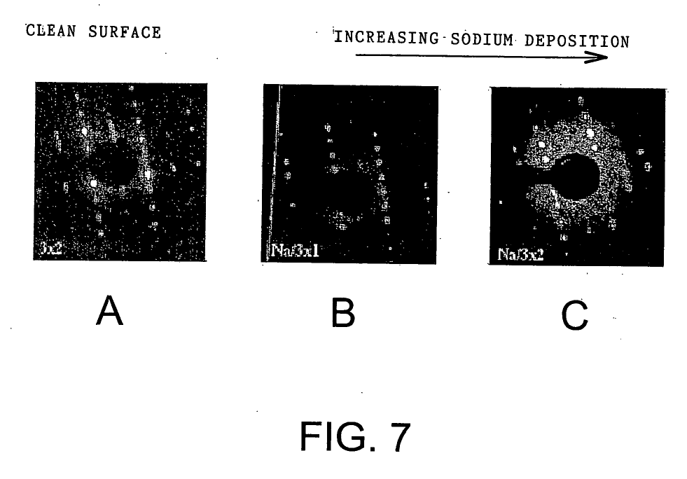

Na clusters are identified by means of a plasmon at 3.1 eV corresponding exactly to the energy of Na spherical clusters. Results also suggest that sodium clusters are regularly spaced and that their size tends to reduce when their coverage ratio increases. Indeed for the thickest deposits (from approximately one atomic single layer up to several atomic single layers) and after progressive annealings up to 350° C., the slow electron diffraction diagram becomes very contrasted, thus showing that Na clusters are well organised and regularly spaced on the β-SiC(100) 3×2 surface. We have made photographs of the sodium clusters on β-SiC(100) 3×2 by LEED, in other words by low energy electron diffraction. These photographs show that these Na clusters are well ordered and regularly spaced, with different orders and therefore different spacings as a function of the surface coverage ratio. Refer to the photographs in FIG. 7.

We thus form auto-organised quantum dots of Na by varying the equilibrium between adsorbate-adsorbate and adsorbate-substrate interactions, by controlling the temperature and quantity of metal deposited. This result is very important and the dots obtained are very significantly different from other quantum dots due to the intrinsic properties of alkaline metals such as sodium.

On one hand, these dots are made on the surface of a semiconductor, which is unprecedented, and moreover it is a wide gap semiconductor.

On the other hand, alkaline metals such as Na have a very low electroaffinity. They reduce the work function of the surface considerably, by several electron-volts, and it is possible to obtain a negative electroaffinity condition, in other words a natural electron emitter (with the surface only or exposed to oxygen), or a photoelectron emitter when the system is exposed to light. A similar phenomenon is used for manufacturing of light amplifiers in night vision devices starting from gallium arsenide surfaces covered with Cs and oxygen.

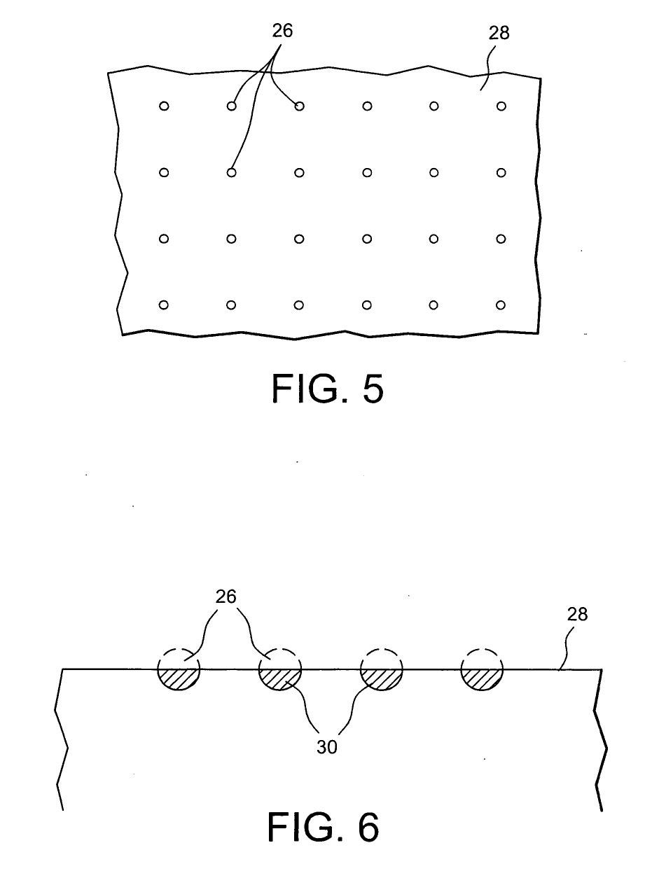

The importance of the result mentioned above (obtaining a lattice of quantum dots of Na) is due to the fact that a lattice of Na dots (clusters) 26 is available (see FIG. 5), with nanometric or sub-nanometric size, that are regularly distributed on the surface of a substrate 28 made of a semiconducting material with a large gap and leave the exposed SiC surface between them.

Therefore, these dots can emit electrons under the effect of a biasing voltage or under the influence of light. This makes it possible to form active matrices for the manufacture of flat screens.

Another important characteristic of alkaline metals, particularly sodium, is due to their exceptional properties as catalysts for oxidation, nitridation, oxynitridation and reaction with organic molecules.

These properties have been demonstrated during work on silicon, III-V semiconductors, metals such as aluminium, and SiC. Refer to documents [10] to [23] mentioned at the end of this description, and to documents [3] and [4] mentioned above.

This opens up a very broad new field of applications that can be called “nano-lithography” or “nano-fabrication”. Due to these Na dots, exposure to oxygen (respectively nitrogen) can result in a localised oxidation or (respectively nitridation) of part of the SiC substrate 28 (see FIG. 6), that is located below each Na cluster, then each of these clusters 26 can be eliminated by a thermal desorption at low temperature (about 650° C.). The result is a super-lattice of SiO₂ (respectively Si₃N₄) dots at nanometric scale.

Similarly, a localised oxynitridation of this part of the SiC substrate can be achieved by exposing the surface covered by Na clusters to NO or N₂O (exposures with low quantities, typically of the order of a few langmuirs), and clusters can then be eliminated by thermal desorption by applying the Na desorption temperature on the substrate considered.

Similarly, with organic molecules, for example CH₃Cl molecules, nanometric silicone dots can be manufactured and other molecules can be used to make other dots such as polymer dots and metalorganic dots: the surface can be exposed to the molecules to obtain silicone dots or polymer dots or metalorganic dots under each of the sodium dots, and the sodium dots can then be eliminated.

The polymer dots (respectively metalorganic dots) mentioned above can also be used as anchor points on the surface on which they are formed, for the molecules used to form these dots.

Finally, the Na—Na interaction can be controlled/optimised by exposing the surface provided with Na dots to small quantities (approximately the order of one langmuir) of inorganic or organic molecules (for example hydrogen, oxygen or any other molecule or element known to those skilled in the art as being capable of interacting with Na or alkaline metals). This will lead to the formation of larger Na clusters.

We will now explain how to obtain sodium quantum dots.

Concerning the preparation of a sample with a β-SiC(100) 3×2 surface we will refer particularly to document [5].

A sample prepared in this way is then placed in a vacuum chamber. A pressure of about 10⁻⁹ Pa is established in the vacuum chamber. Sodium is then deposited on the sample using a zeolite source of the type marketed by the SAES Getters Company, after having perfectly degassed this source such that the pressure increase in the chamber during the deposition does not exceed 3×10⁻⁹ Pa. The result is thus sodium clusters on the surface.

The deposition takes place at room temperature (about 25° C.) and the Na source is placed at less than 10 cm from the sample, preferably at a distance of approximately 3 cm to 5 cm from this sample, the optimum distance being about 3 cm.

The next step is annealings (at temperatures of a few hundred degrees, for example 350° C., during a time lasting from a few seconds to a few minutes) of the β-SiC(100) 3×2 surface covered with sodium clusters. These annealings make it possible to optimise the number, size and position of these clusters. They may be done using the Joule effect, by passing an electrical current through the SiC sample and controlling its temperature, for example using a pyrometer or a thermocouple.

In the examples given above, sodium was used to form the clusters. However, sodium could be replaced by other alkaline metals, and particularly potassium, Cs, Rb or alkaline-earth metals, for example such as Mg, Ca and Ba.

Furthermore, in these examples, an SiC substrate was used that in the context of this invention could be of the cubic or hexagonal type, rich in Si and/or C. However, this substrate could be replaced by a diamond substrate or by a substrate made of a covalent semiconducting material, for example Si or Ge, or by a substrate made of an III-V composite semiconducting material (for example GaAs, InP, GaSb, GaP or InAs) or an II-VI composite semiconducting material (for example CdTe, ZnO or ZnTe).

Furthermore, the low temperature thermal desorption mentioned above may be used within a temperature range varying from room temperature (about 25° C.) to the desorption temperature of the metal considered on the substrate considered.

The documents mentioned above are as follows:

[10] SiO₂-Si interface formation by catalytic oxidation using alkali metals and removal of the catalyst

P. Soukiassian, T. M. Gentle, M. H. Bakshi and Z. Hurych

Journal of Applied Physics 60, 4339 (1986)

[11] Exceptionally large enhancement of InP(110) oxidation rate by cesium catalyst

P. Soukiassian, M. H. Bakshi and Z. Hurych

Journal of Applied Physics 61, 2679 (1987)

[12] Catalytic oxidation of semiconductors by alkali metals

P. Soukiassian, T. M. Gentle, M. H. Bakshi, A. S. Bommannavar and Z. Hurych

Physica Scripta (Sweden), 35, 757 (1987)

[13] Electronic promoters and semiconductor oxidation: alkali metals on Si(111)2×1 surface

A. Franciosi, P. Soukiassian, P. Philip, S. Chang, A. Wall, A. Raisanen and N. Troullier

Physical review B 35, Rapid Communication, 910 (1987)

[14] Si₃N₄-Si interface formation by catalytic nitridation using alkali metals overlayers and removal of the catalyst: N2/Na/Si(100)2×1

P. Soukiassian, T. M. Gentle, K. P. Schuette, M. H. Bakshi and Z. Hurych

Applied Physics Letters 51, 346 (1987)

[15] Electronic properties of O₂ on Cs or Na overlayers adsorbed on Si(100)2×1 from room temperature to 650° C.

P. Soukiassian, M. H. Bakshi, Z. Hurych and T. M. Gentle

Physical Review B 35, Rapid Communication, 4176 (1987)

[16] Thermal growth of SiO₂-Si interfaces on a Si(111)7×7 surface modified by cesium

H. I. Starnberg, P. Soukiassian, M. H. Bakshi and Z. Hurych

Physical Review B 37, 1315 (1988)

[17] Alkali metal promoted oxidation of the Si(100)2×1 surface: coverage dependence and non-locality

H. I. Starnberg, P. Soukiassian and Z. Hurych

Physical Review B 39, 12775 (1989)

[18] Alkali metals and semiconductor surfaces: electronic, structural and catalytic properties

P. Soukiassian and H. I. Starnberg (Guest Article)

in Physics and Chemistry of Alkali Metal Adsorption, Elsevier Science Publishers B. V.,

Amsterdam, Netherlands, Materials Science Monographs 57, 449 (1989)

[19] Catalytic nitridation of a Il-V semiconductor using alkali metal

P. Soukiassian, T. Kendelewicz, H. I. Stamberg, M. H. Bakshi and Z. Hurych

Europhysics Letters 12, 87 (1990)

[20] Room temperature nitridation of gallium arsenide using alkali metal and molecular nitrogen

P. Soukiassian, H. I. Stamberg, T. Kendelewicz and Z. D. Hurych

Physical Review B 42, Rapid Communication 3769 (1990)

[21] Rb and K promoted nitridation of cleaved GaAs and InP surfaces at room temperature

P. Soukiassian, H. I. Stamberg and T. Kendelewicz

Applied Surface Science 56, 772 (1992)

[22] Al₂O₃+x/Al interface formation by promoted oxidation using an alkali metal and removal of the catalyst

Y. Huttel, E. Bourdié, P. Soukiassian, P. S. Mangat and Z. Hurych

Applied Physics Letters 62, 2437 (1993)

[23] Direct and Rb-promoted SiOₓ/β-SiC(100) interface formation

M. Riehl-Chudoba, P. Soukiassian, C. Jaussaud and S. Dupont

Physical Review B 51, 14300 (1995).

1. A set of nano-objects (4, 10, 12, 22, 24), particularly atomic threads, single dimensional nano-structures and quantum dots, this set being characterised in that the nano-objects are made of a metal and are formed on the surface (2, 6, 14) of a substrate made of a monocrystalline semiconducting material.

2. A set of nano-objects according to claim 1, in which the monocrystalline semiconducting material is chosen from among monocrystalline silicon carbide, monocrystalline diamond, covalent monocrystalline semiconductors, and composite monocrystalline semiconductors.

3. A set of nano-objects according to claim 2, in which the substrate is a monocrystalline substrate of silicon carbide in the cubic phase.

4. A set of nano-objects according to claim 3, in which the surface (2) is a cubic silicon carbide surface, rich in β-SiC (100) 3×2 silicon.

5. A set of nano-objects according to claim 1, in which the nano-objects are three-dimensional clusters (4) of the metal on the surface.

6. A set of nano-objects according to claim 5, in which the clusters are distributed in an orderly manner on the surface and thus form a lattice of metal dots.

7. A set of nano-objects according to claim 3, in which the surface (6, 14) is a cubic silicon carbide surface which is Si terminated, β-SiC(100) c(4×2), and the nano-objects are parallel atomic threads (10, 22) or parallel single-dimensional nanometric strips (12, 24) of the metal.

8. A set of nano-objects according to claim 7, in which the surface (6, 14) comprises parallel atomic threads (8, 20) of Si, the atomic threads and single dimensional strips of the metal being perpendicular to these atomic threads of Si.

9. A set of nano-objects according to claim 1, in which the surface comprises passivated areas (15) and non-passivated areas (16, 18) and the nano-objects are formed on these non-passivated areas of the surface.

10. A set of nano-objects according to claim 1, in which the metal is chosen from among metals for which the d band is full, jellium type metals, alkaline metals and transition metals.

11. A set of nano-objects according to claim 10, in which the metal is chosen from among sodium and potassium.

12. Process for making a set of nano-objects, in which a surface (2, 6, 14) of a substrate made of a monocrystalline semiconducting material is prepared, and a metal is deposited on the surface thus prepared.

13. Process according to claim 12, in which the monocrystalline semiconducting material is chosen from among monocrystalline silicon carbide, monocrystalline diamond, covalent monocrystalline semiconductors and monocrystalline composite semiconductors.

14. Process according to claim 13, in which the substrate is a monocrystalline substrate of silicon carbide in the cubic phase.

15. Process according to claim 12, in which the metal is deposited at a temperature greater than or equal to room temperature.

16. Process according to claim 14, in which a surface (2) of cubic silicon carbide rich in silicon β-SiC(100) 3×2 is prepared, and the metal is deposited on the surface thus prepared.

17. Process according to claim 14, in which a silicon carbide surface (6,14) which is Si terminated β-SiC(100) c(4×2) is prepared, the metal is deposited at room temperature on the surface thus prepared and, by surface migration of metal atoms along lines of Si—Si dimers of the surface c(4×2), atomic threads of the metal are obtained that are parallel to the lines of Si—Si dimers.

18. Process according to claim 17, in which a thermal annealing of the substrate is carried out at a temperature below the total desorption temperature of the metal.

19. Process according to claim 12, in which the metal is deposited by vacuum evaporation.

20. Process according to claim 12, in which the metal is deposited in an inert atmosphere.

21. Process according to claim 12, in which passivated areas (15) are formed on the thus prepared surface and the metal is then deposited on non-passivated areas (16, 18) of this surface.

22. Process according to claim 12, in which the metal is chosen from among metals for which the d band is full, jellium type metals, alkaline metals and transition metals.

23. Process according to claim 22, in which the metal is chosen from among sodium and potassium.

24. Process according to claim 17, in which a laser is used to obtain desorption of the metal either by thermal interaction of the beam emitted by this laser over the surface covered with metal, or by desorption of the metal induced by electronic transitions.

25. Process according to claim 14, in which the surface is an sp type C terminated surface, namely the β-SiC(100) c(2×2) surface.

26. Process according to claim 25, in which this surface comprises atomic lines of sp3 type C and atomic threads of metal are formed that are either parallel or perpendicular to the atomic lines of C.

27. Process according to claim 12, in which a lattice of metal dots is formed on the surface of the substrate made of monocrystalline semiconducting material, the substrate material located under the dots is locally transformed and the lattice of dots is eliminated thus to obtain a super-lattice of dots made of the transformed material.

28. Process according to claim 27, in which the local transformation of the substrate material is chosen from among oxidation, nitridation and oxynitridation to obtain a super-lattice of dots made of the oxide, nitride or oxynitride of the material.

29. Super-lattice of dots, obtained using the process according to claim 28, these dots being made of the oxide, nitride or oxynitride of a monocrystalline semiconducting material and formed at the surface of a substrate of this material.
